(19) United States
(12) Patent Application Publication
(10) Pub. No.: US 2006/0282726 A1
(43) Pub. Date: Dec. 14, 2006

(54) Semiconductor device, and apparatus and method for supporting design of semiconductor device

(75) Inventor: Mitsuyuki Katsuzawa, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/434,896

(22) Filed: May 17, 2006

(30) Foreign Application Priority Data
May 18, 2005 (JP) 2005-145963

(51) Int. Cl. G01R 31/28

(52) U.S. Cl. 714/724

(57) ABSTRACT

A semiconductor device includes a logic circuit section having a plurality of logic circuits and configured to achieve a predetermined logical function; and a probing circuit connected with the logic circuit section. The probing circuit is not related to the predetermined logical function and comprises a diffusion layer used in a LVP (Laser Voltage Probing) method.

### BACKGROUND OF THE INVENTION

1. Field of the Invention

The present invention relates to a semiconductor device and a method of manufacturing the same, a system and method for supporting design of a semiconductor device, and a method of verifying an operation of a semiconductor device.

2. Description of the Related Art

Japanese Laid Open Patent Publication (JP-A-Heisei 5-256917) discloses a technique for using an electron beam (EB) method to analyze a semiconductor device. In the EB method, it is required to open a semiconductor package and to expose a wiring layer into which an analysis target signal is transferred. Exposing the wiring layer is very difficult if an LSI has a multi-layer structure. Even if it can be exposed, there is a case that addition of wirings for the EB method causes increase of wiring delay, resulting in a great difference from an actual timing.

In order to solve this problem, an LVP (Laser Voltage Probe) method is developed in which a laser beam is irradiated from a semiconductor substrate side of a semiconductor device to measure the waveform of an internal signal. A target measured by this LVP method is a carrier concentration in a diffusion layer. FIG. 1 shows a measurement example of a semiconductor device by the LVP method, which is shown in “Comparison of Laser and Emission Based Optical Probe Techniques” by W. L. Steven, et al. (http://www.nptest.com/assets/about/pdf/probe_comparison_laser_emission_{—}2001_pdf). Referring to FIG. 1, a measurement will be described of a cross section of a part of the semiconductor device to attain a predetermined logic operation. The semiconductor device in this conventional example depends on a 0.18 μm rule. A P-channel MOS transistor and an N-channel MOS transistor are connected in series, the P-channel MOS transistor is formed inside an N-well 102, and the N-channel MOS transistor is formed on a P-substrate 110. A drain 113 of the P-channel MOS transistor is connected through a conductor 116 with a drain 112 of the N-channel MOS transistor and outputs a signal based on signals to be supplied to the gates of the P-channel MOS transistor and the N-channel MOS transistor.

With reference to FIG. 1, a laser beam emitted from a light source is transmitted through a semi-transparent film, focused by an objective lens and irradiated to the semiconductor device. The semiconductor device is transparent to the light having the wavelength of 0.9 to 2.5 μm. The emitted laser beam invades into the semiconductor device, and the laser beam focused by the objective lens is irradiated to a drain diffusion layer of the N-channel MOS transistor. The magnitude of the irradiated laser beam is modulated in accordance with the carrier concentration inside the drain diffusion layer 112. The laser beam whose magnitude is modulated is supplied through the objective lens to the semi-transparent film, reflected thereby and supplied to a detector (not shown). The detector can detect a signal from the laser beam whose magnitude is modulated and then check the operation of the logic circuit from the detected signal.

In this way, conventionally, the laser beam was irradiated to the diffusion layer of a part of the logic circuit of the semiconductor device, and the operation of the logic circuit was consequently checked. This was possible because the semiconductor device was designed in accordance with the 0.18 μm rule. However, at present, the design rule becomes further minute, and the size of the diffusion layer becomes small. In this case, even if the laser beam is tried to be focused, there is a limit. For example, when the transistors small in size are placed adjacent to each other, the laser beam is irradiated even to a diffusion layer of a different transistor other than a targeted transistor. Thus, the measurement of the waveform of a desirable position becomes impossible.

### SUMMARY OF THE INVENTION

In an aspect of the present invention, a semiconductor device includes a logic circuit section having a plurality of logic circuits and configured to achieve a predetermined logical function; and a probing circuit connected with the logic circuit section. The probing circuit is not related to the predetermined logical function and comprises a diffusion layer used in a LVP (Laser Voltage Probing) method.

Here, the plurality of logic circuits may be divided into a plurality of circuit blocks based on a block designation, and the probing circuit may be provided for at least one specified circuit block of the plurality of circuit blocks or at least one specified logic circuit of the plurality of logic circuits.

Also, the diffusion layer of the probing circuit may have a size equal to or larger than a diameter of a laser beam used in the LVP method.

Also, the probing circuit is one of a buffer circuit, an inverter circuit, an AND circuit, a NAND circuit, an OR circuit, a NOR circuit, a three state buffer circuit, a flip-flop circuit and a latch circuit.

Also, the semiconductor device may have a plurality of the probing circuits, and the plurality of probing circuits may be different in kind.

Also, the probing circuit may be an AND circuit containing a plurality of transistors, and One of inputs of the AND circuit may be connected with the logic circuit section and another one of the inputs of the AND circuit may be connected with a mode signal. The mode signal may be outputted when the LVP method is carried out. At least one of the plurality of transistors may be activated in response to the mode signal, and the diffusion layer of the activated transistor is used for measurement of the LVP method.

Also, the probing circuit may be an AND circuit containing a plurality of transistors, and one of inputs of the AND circuit may be connected with the logic circuit section, and another one of the inputs of the AND circuit is connected with a ground voltage or a power supply voltage. At least one of the plurality of transistor may be activated, and the diffusion layer of the activated transistor may be used for measurement of the LVP method.

In another aspect of the present invention, a semiconductor device includes a logic circuit of a plurality of devices; and a probing circuit connected with an output of at least one device of the plurality of devices. A diffusion layer of the probing circuit is larger than a diffusion layer of the device.

Here, an output of the probing circuit may be open.

Also, the probing circuit may be activated in a probing mode and is inactivated in a usual operation mode.

In another aspect of the present invention, a design supporting system of a semiconductor device includes a logic circuit section having a plurality of logic circuits to achieve a predetermined logical function, and a probing circuit connected with the logic circuit section, and the probing circuit is not related to the predetermined logical function and comprises a diffusion layer used in a LVP (Laser Voltage Probing) method. The design supporting system includes a net list configured to store a circuit configuration data showing a configuration of the logic circuit section; a layout database configured to store a first layout data showing a layout of the logic circuit section; an output unit; an input unit; and a processing unit. The processing unit refers to the net list and the layout database, to read out the circuit configuration data from the net list and the first layout data from the layout database. Then, the processing unit displays a configuration of the logic circuit section on the output unit based on the circuit configuration data, specifies a portion of the logic circuit section in response to a specification instruction from the input unit as a specification portion. Also, the processing unit generates a second layout by automatically placinging a specification probing circuit in said specification portion of said first layout and automatically connecting said specified probing circuit to said first layout, and displays said second layout on said output unit.

Also, the specification probing circuit may be a probing circuit selected from a plurality of probing circuits.

Also, the plurality of logic circuits may be divided into a plurality of circuit blocks based on a block specification. At least one of the plurality of logic circuits or at least one of the plurality of circuit blocks may be specified as the specification portion.

Also, the design supporting system may further include a part database configured to store a part data showing a size and a delay time of each of a plurality of circuit elements which contain the plurality of logic circuits, and a part data showing a size and a delay time of the probing circuit. The processing unit may refer to the part database and carries out a timing verification based on the second layout.

Also, the processing unit may carry out a layout correcting process for modifying the second layout such that a timing condition is met at a specific section of said second layout when the timing condition is not met at the specific section of the second layout in the timing verification. In this case, the layout correcting process may be one of a process of replacing a logic circuit in the specific section by another logic circuit having a same logic function as the logic circuit, a process of changing a placement position of the logic circuit in the specific section, and a process of deleting a placed probing circuit in the specific section.

Also, the processing unit may specify the specification portion based on a signal name or a coordinate from the input unit.

Also, the processing unit may specify a non-placement circuit block based on a non-placement block name from the input unit and may specify circuit blocks other than the non-placement circuit block in the logic circuit section as the specification portion. In this case, the processing unit may specify a non-placement signal line based on the non-placement signal name from the input unit and may specify signal lines other than the non-placement signal line in the logic circuit section as the specification portion.

Also, the processing unit may insert the probing circuit into each of inputs and outputs of each of the plurality of logic circuits related to the specification portion.

Also, the processing unit may insert the probing circuit into each of inputs and outputs of each of the plurality of circuit blocks in the specification portion.

In still another aspect of the present invention, a design supporting method is provided of a semiconductor device which includes a logic circuit section having a plurality of logic circuits and configured to achieve a predetermined logical function, and a probing circuit connected with the logic circuit section, wherein the probing circuit is not related to the predetermined logical function and comprises a diffusion layer used in a LVP (Laser Voltage Probing) method. The design supporting method may be achieved by displaying a configuration of the logic circuit section on an output unit based on a net list; by specifying at least one logic circuit or at least one circuit block which containing at least one logic circuit in response to an instruction from an input unit as a specification portion; and by automatically placing a specified probing circuit in the specification portion of a first layout and automatically connecting the specified probing circuit to the logic circuit section to generate a second layout.

Also, the design supporting method may be achieved by further designating one of a plurality of probing circuits as a specification probing circuit by referring to a part database.

Also, the design supporting method may be achieved by further carrying out a timing verification based on the plurality of logic circuits and interconnections in the circuit configuration.

Also, the design supporting method may be achieved by further carrying out a layout correcting process for modifying the second layout such that a timing condition is met at a specific section when the timing condition is not met at the specific section of the second layout as a result of timing verification. In this case, the layout correcting process is one of a process of replacing a logic circuit in the specific section by another logic circuit having a same logic function as the logic circuit, a process of changing a placement position of the logic circuit in the specific section, and a process of deleting a placed probing circuit in the specific section.

Also, the specifying may be achieved by specifying as a specification portion, the at least one logic circuit based on a signal name or a coordinate from an input unit and the at least one circuit block based on a placement block name. In this case, the specifying may be achieved by specifying a non-placement circuit block based on a non-placement block name from the input unit; and by specifying circuit blocks other than the non-placement circuit block in the logic circuit section as the specification portion.

Also, the specifying may be achieved by specifying a non-placement signal line based on the non-placement signal name from the input unit; and by specifying signal lines other than the non-placement signal line in the logic circuit section as the specification portion.

Also, the generating a second layout may be achieved by inserting the probing circuit in outputs of the logic circuit and in inputs and outputs of the circuit block in the specification portion.

### BRIEF DESCRIPTION OF THE DRAWINGS

FIG. 1 is a diagram showing a conventional LVP method;

FIG. 2 is a block diagram showing a configuration of a design supporting apparatus according to a first embodiment of the present invention;

FIG. 3 is a flow chart showing a method of designing a semiconductor device of the present invention;

FIG. 4 is a flowchart showing an operation of the design supporting system according to the first embodiment of the present invention;

FIGS. 5 to 9 are examples in which probing circuits are inserted;

FIG. 10 is a diagram showing an example in which a buffer is inserted as the probing circuit;

FIG. 11 is a diagram showing an example in which an inverter is inserted as the probing circuit;

FIG. 12 is a diagram showing an example in which an AND circuit is inserted as the probing circuit;

FIG. 13 is a diagram showing an example in which the AND circuit is inserted as the probing circuit; and

FIG. 14 is a diagram showing an example in which the AND circuit as the probing circuit is used as a spare cell.

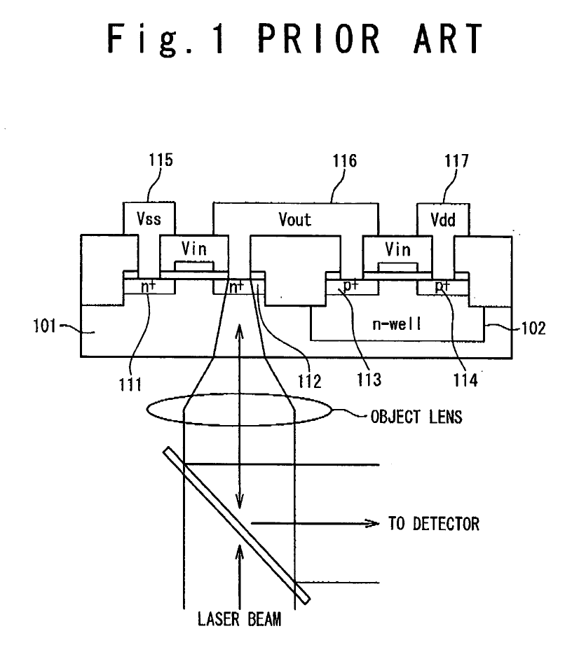

### DESCRIPTION OF THE PREFERRED EMBODIMENTS

Hereinafter, a semiconductor device according to the present invention and a design supporting system of the semiconductor device will be described in detail with reference to the attached drawings.

The semiconductor device of the present invention has a logic circuit section having a plurality of logic circuits to attain a predetermined logic function and probing circuits connected to the logic circuit section. The probing circuit has no relation to the predetermined logic function, and a diffusion layer of the probing circuit is used in a LVP (Laser Voltage Probing) method. In the semiconductor device of the present invention, a diffusion layer of a transistor in the logic circuit section is smaller than a diameter of a laser beam used in the LVP method, through the miniaturization of the design rule. For this reason, the diffusion layer of the transistor in the probing circuit activated at the time of the operation check is larger than the diameter of the laser beam, namely, larger than the diffusion layer of the logic circuit. Consequently, the operation can be stably checked.

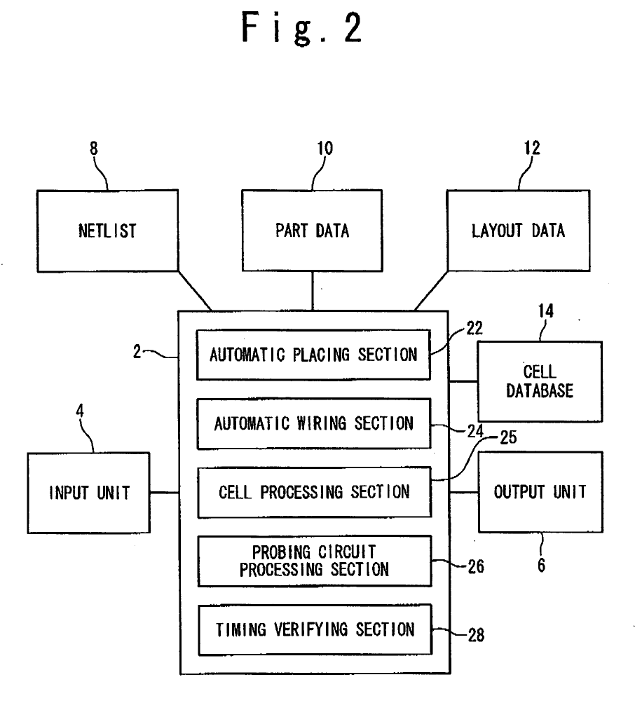

FIG. 2 is a block diagram showing a configuration of a design supporting apparatus according to the first embodiment of the present invention. Referring to FIG. 2, the design supporting system of the present invention includes a processing unit 2, an input unit 4 such as a keyboard and a mouth, and an output unit 6 such as a display unit. The input unit 4 outputs a data and a command, which are inputted by a user, to the processing unit 2. The output unit 6 displays a data and a question, which are outputted by the processing unit 2. The processing unit 2 is realized by executing a computer program, and functionally includes an automatic placement section 22, an automatic wiring section 24, a cell processing section 25, a probing circuit processing section 26 and a timing verifying section 28. The automatic placement section 22 automatically places a specified cell pattern or a probing circuit pattern on a specified position, under the controls of the processing sections 25 and 26. At this time, the automatic placement section 22 determines whether or not there is a space where the cell pattern or probing circuit pattern can be placed, namely, whether or not the placement is possible. If the placement is impossible, a warning is outputted through the output unit 6 from the processing unit 2 to the user. The automatic wiring section 24 automatically connects the placed cell pattern or probing circuit pattern adequately under the controls of the processing sections 25 and 26. The cell processing section 25 sequentially activates the automatic placement section 22 and the automatic wiring section 24, when the cell pattern is specified. The probing circuit processing section 26 sequentially activates the automatic placement section 22 and the automatic wiring section 24, when the probing circuit pattern is specified. When the placement and wiring of the cell pattern and the probing circuit pattern are ended, the timing verifying section 28 is activated.

Also, the design supporting system includes a net list 8, a part database 10, a layout database 12 and a cell database 14, and they are connected to the processing unit 2. The net list 8 stores data of parts constituting the logic circuit sections in the semiconductor device and data indicating its connection relation. The part database 10 stores data of each of the parts (components) of the logic circuit section in the semiconductor device. The parts include not only the logic circuit but also a wiring, and further include the probing circuits related to the present invention. The part data includes a drive performance, an operation (delay) time and the like. The cell database 14 stores cell patterns and probing circuit patterns, which correspond to the parts stored in the part database 10. The layout database 12 stores a layout data of the logic circuit section in the semiconductor device.

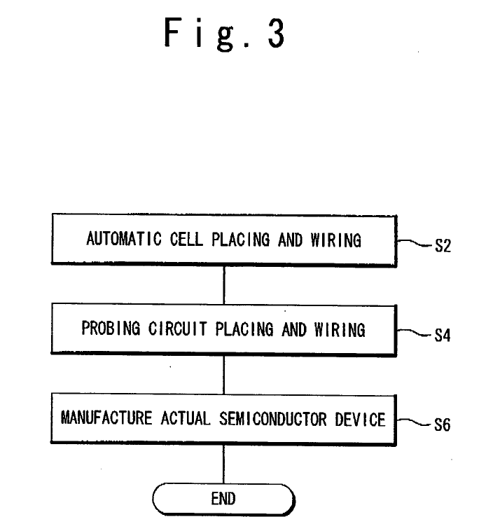

A method of manufacturing the semiconductor device of the present invention will be described below with reference to FIG. 3. At a step S2, the cells for the logic circuit section to attain the predetermined logic functions are automatically placed and wired. In detail, the cell processing section 25 activates the automatic placement section 22 and the automatic wiring section 24. The automatic placement section 22 refers to the net list 8 and determines each of the parts constituting the logic circuit section, and then refers to the cell database 14 in accordance with each of the parts to obtain the cell pattern corresponding to each part, and further places on a specified position of the cell pattern. The automatic wiring section 24 refers to the net list 8 and automatically wires the placed cell pattern. In this example, the cells are automatically placed and automatically wired. However, they may be manually placed and wired. The above-mentioned processes are executed for all of the parts in the circuit configuration data stored in the net list 8. The layout of the logic circuit section for the semiconductor device is stored in the layout database 12.

Next, at a step S4, the probing circuit is automatically placed and wired. In detail, the probing circuit processing section 26 activates the automatic placement section 22 and the automatic wiring section 24. The automatic placement section 22 refers to the net list 8 and displays the circuit configuration data on the output unit 6. The automatic placement section 22 determines a portion into which the probing circuit pattern should be inserted, namely, an insertion specification portion, in accordance with an instruction of the user which is outputted from the input unit 4. After that, the automatic placement section 22 refers to the cell database 14 to determine the probing circuit pattern, and reads out the logic circuit section layout generated at the above step from the layout database 12, and then superimposes the probing circuit pattern on the logic circuit section layout. Subsequently, the automatic wiring section 24 refers to the net list 8 and automatically wires the placed cell pattern to the logic circuit section. Through the above-mentioned steps, the semiconductor device layout with the probing circuits is generated and stored in the layout database 12.

When the generation of the semiconductor device layout is completed, the timing verifying section 28 is activated. The timing verifying section 28 refers to the net list 8, the part database 10 and the layout database 12, and determines whether or not each portion in the logic circuit section satisfies a predetermined timing condition. A timing modifying process is applied to a portion which does not satisfy the timing condition. If each portion of the logic circuit section satisfies the timing condition, the layout at that time is determined as the final layout and stored in the layout database 12.

After that, at a step S6, various masks are produced in accordance with the final layout. Then, they are used to manufacture the semiconductor device.

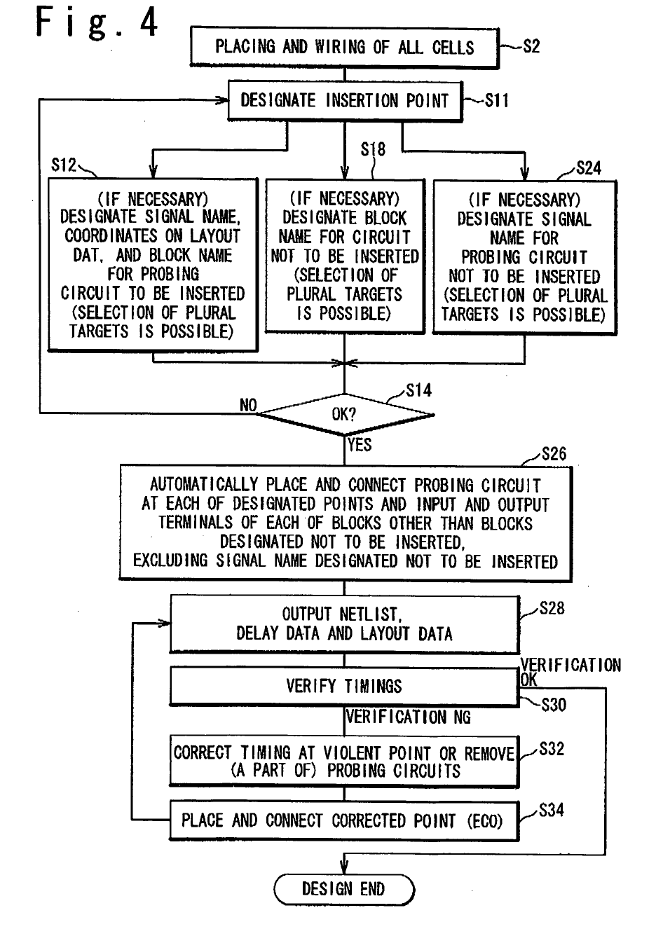

The detail of the design of the semiconductor device according to the design supporting system will be described below with reference to FIG. 4. As shown in FIG. 4, at the step 32, as mentioned above, the logic circuit section layout for the logic circuit in the semiconductor device is generated and stored in the layout database 12. After that, in the steps from the step S11, the placement and wiring of the probing circuit pattern are executed as follows.

At the step S11, the probing circuit processing section 26 is activated. The probing circuit processing section 26 determines the portion into which the probing circuit should be inserted, namely, the insertion specification portion. For this reason, the probing circuit processing section 26 reads out the circuit configuration data from the net list 8, and displays the circuit diagram on the output unit 6 in accordance with it, and then inquires of the user a position or block into which the probing circuit should be inserted, or a position or block into which this should be not inserted. In this way, at the step S11, any of steps S12, S18 and S24 may be next selected.

At the step S12, the user can input a signal name on the wiring, into which the probing circuit should be inserted, from the input unit 4. Or, the user specifies the logic circuit into which the probing circuit should be inserted on its output side, from the input unit 4. At this time, the logic circuit or wiring inside the circuit configuration displayed on the output unit 6 may be clicked, thereby specifying the logic circuit or wiring. Also, at this time, a circuit block which contains at least one logic circuit may be specified. Or, a mouth may be used to specify a range, and all of the signals or wirings within the range may be specified. When the circuit block is specified, the probing circuit is added to the respective input terminals and the respective output terminals of the circuit block. The circuit block can be specified, for example, by drawing a cursor while clicking the mouth. In this way, the circuit block can be arbitrarily specified. In the above-mentioned processes, a plurality of signal names, a plurality of logic circuits and a plurality of circuit blocks can be specified. Also, the circuit block may be specified by the user and specified in units of macros.

In the above-mentioned example, the predetermined probing circuit is inserted into the insertion specification portion. However, the different probing circuit may be inserted for each insertion specification portion. In that case, when the signal name, logic circuit or circuit block is specified, the probing circuit processing section 26 refers to the part database 10 and displays the plurality of circuit blocks on the output unit 6. Then, the probing circuit to be inserted may be specified by the user. Consequently, the probing circuit can be used as a spare cell, which will be described later.

Next, at the step S14, the probing circuit processing section 26 inquires of the user whether or not the specification of the signal name, logic circuit or circuit block has been completed. If there is an answer of non-completion through the input unit 4 from the user, the step S11 is again executed.

Next, it is supposed that the step S18 is executed. At the step S18, the circuit block into which the probing circuit should not be inserted is specified, in similar manner to the step S12. The process of the step S18 can specify the plurality of circuit blocks.

Next, the step S14 is executed similarly to the above-mentioned case. At the step S14, the probing circuit processing section 26 inquires of the user whether or not the specification of the signal name, logic circuit or circuit block has been completed. If there is the answer of the non-completion through the input unit 4 from the user, the step S11 is again executed.

Next, at the step S11, it is supposed that a step S24 is selected and executed. At the step S24, the signal or wiring into which the probing circuit should not be inserted is specified in a similar manner to the step S12. In the above-mentioned processes, the plurality of signals or wirings can be specified.

Next, similarly to the foregoing case, the step S14 is executed. At the step S14, the probing circuit processing section 26 inquires of the user whether or not the specification of the signal name, logic circuit or circuit block has been completed. If there is the answer of the non-completion through the input unit 4 from the user, the step S11 is again executed. When the answer of the completion is obtained, a step S26 is next executed.

In this way, each of the steps S12, S18 and S24 maybe executed only once or several times. Also, for example, after the step S12, the step S18 may be executed, and after that, the step S12 may be again executed. In this way, the position into which the probing circuit should be inserted, the logic circuit or the circuit block may be arbitrarily specified.

At the step S26, the probing circuit processing section 26 inquires of the user which of the following insertion modes is selected. In an insertion mode 1, when the probing circuit can be inserted, the probing circuit is always inserted into the insertion specification portion without any determination of whether or not a logic of a portion into which the probing circuit is inserted is equivalent to a logic of a portion into which the probing circuit is already inserted. In an insertion mode 2, when the probing circuit can be inserted, if the logic of the portion into which the probing circuit is inserted is equivalent to the logic of the portion into which the probing circuit is already inserted, the probing circuit is not always inserted. In an insertion mode 3, even if the logic of the portion into which the probing circuit is inserted is equivalent to the logic of the portion into which the probing circuit is already inserted, when the insertion is possible, the probing circuit is inserted. In an insertion mode 4, if the logic of the portion into which the probing circuit is inserted is equivalent to the logic of the portion into which the probing circuit is already inserted, whether or not the probing circuit is inserted is interactively determined. One of the four insertion modes is selected.

Next, the probing circuit processing section 26 drives the automatic placement section 22 and the automatic wiring section 24. The automatic placement section 22 refers to the net list 8, the cell database 14 and the layout database 12 and inserts the probing circuit pattern into the logic circuit section layout. At the same time, the probing circuit is also added to the circuit configuration data of the net list 8.

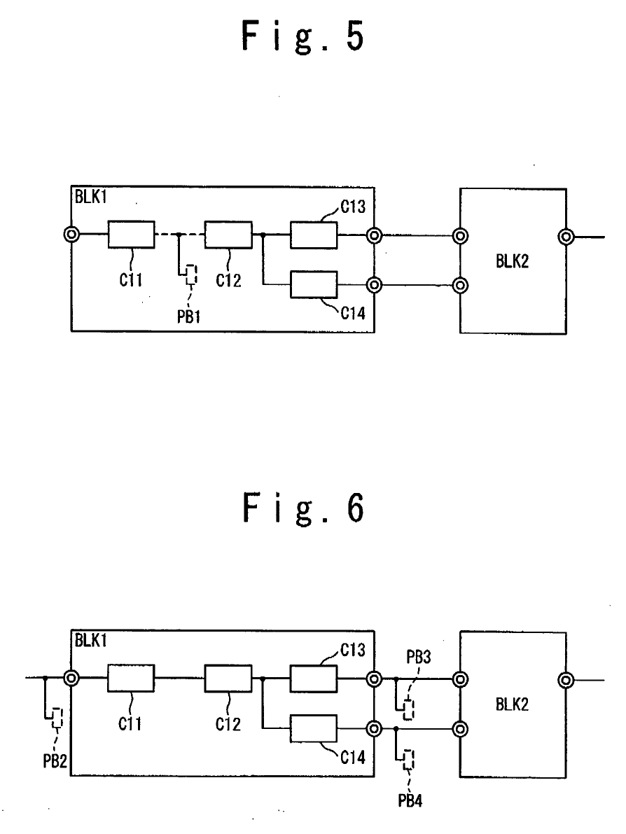

FIG. 5 shows an example of the insertion of the probing circuit when only the signal name is specified. In the circuit configuration shown in FIG. 5, two circuit blocks BLK1 and BLK2 are shown. However, this is illustrated only for convenience, and they are not actually specified. At the step S12, the output of a logic circuit C11 is specified, and a probing circuit PB1 is added to the output side of the logic circuit C11.

FIG. 6 shows an example of the insertion of the probing circuit when only the circuit block is specified. In the circuit configuration shown in FIG. 6, the two circuit blocks BLK1 and BLK2 are shown. However, at the step S12, only the circuit block BLK1 is specified. Probing circuits PB2 to PB4 are added to the input terminal and output terminals of the circuit block BLK1.

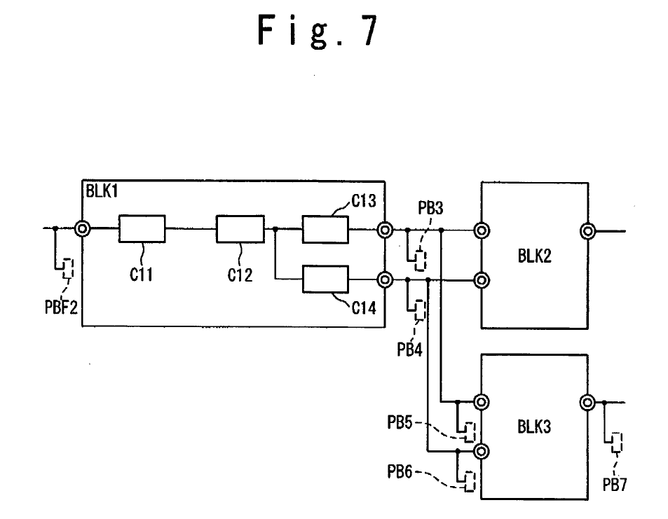

FIG. 7 shows an example of the insertion of the probing circuit when the circuit block into which the probing circuit should not be inserted is specified. In the circuit configuration shown in FIG. 7, three circuit blocks BLK1, BLK2 and BLK3 are indicated. For example, FIG. 7 shows a case where although the three circuit blocks are specified at the step S12, the circuit block BLK2 is specified at the step S18. In FIG. 7, the probing circuits PB2 to PB7 are inserted into the respective input terminals and the respective output terminals in each of the circuit block BLK1 and the circuit block BLK3. The output terminals of the circuit block BLK1 are connected to the input terminals of the circuit block BLK3. Thus, at the corresponding terminal, the logic is equivalent. However, it would be understood that the case where the probing circuit is inserted is the case where one of the insertion modes 1 to 4 other than the mode 3 is specified.

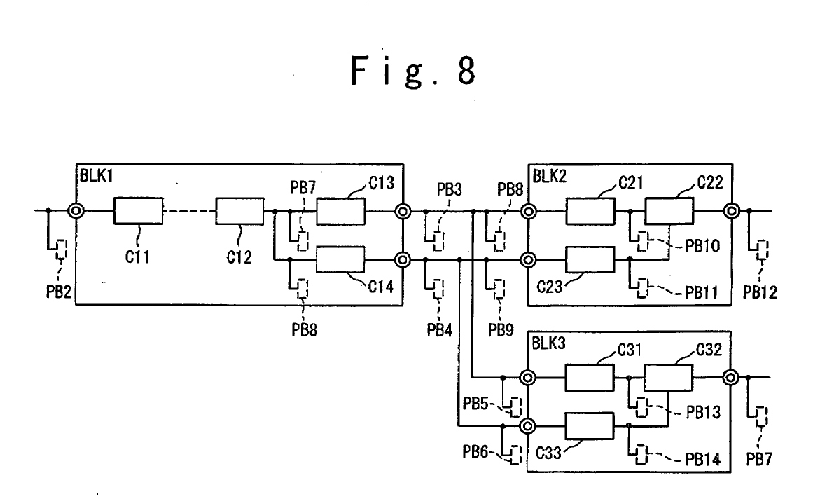

FIG. 8 shows an example of the insertion of the probing circuit when only the signal into which the probing circuit should not be inserted is specified. In the circuit configuration shown in FIG. 8, three circuit blocks BLK1, BLK2 and BLK3 are indicated. In FIG. 8, the output signal or output wiring of the logic circuit C11 inside the circuit block BLK1 is specified as the signal or wiring into which the probing circuit should not be inserted. In this way, probing circuits PB2 to PB14 are inserted into the respective input terminals and the respective output terminals in each of the circuit blocks BLK1, BLK2 and BLK3 and the circuits inside each of the circuit blocks BLK1, BLK2 and BLK3. Here, the output terminals of the circuit block BLK1 is connected to the input terminals of the circuit block BLK3. Thus, at the corresponding terminal, the logic is equivalent. However, it could be understood that the case where the probing circuit is inserted is the case where one of the insertion modes 1 to 4 other than the mode 3 is specified.

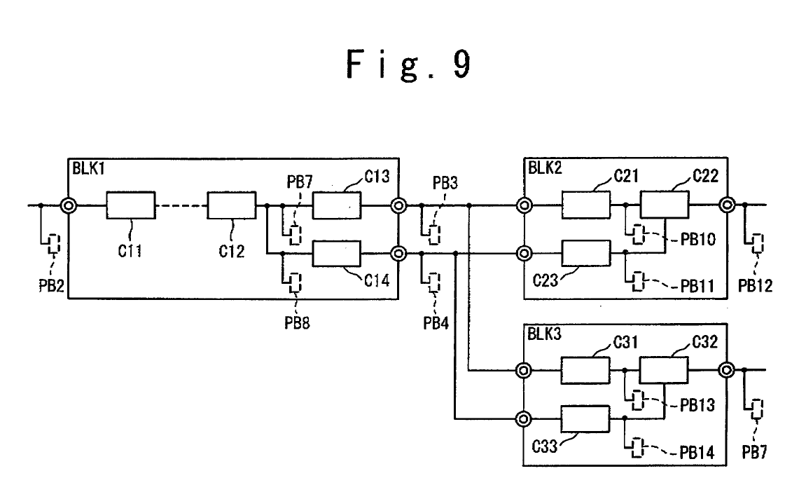

Although FIG. 9 is similar to FIG. 8, the probing circuit is not inserted into the input terminals of the circuit blocks BLK2 and BLK3. The input terminals of the circuit blocks BLK2 and BLK3 are connected to the output terminals of the circuit block BLK1. This shows the case when the insertion mode 3 is executed.

Next, after the execution of the step S26, a step S28 is executed. At the step S28, the probing circuit processing section 26 activates the timing verifying section 28. The timing verifying section 28 refers to the net list 8, the part database 10 and the layout database 12 and carries out the timing verification on each unit of the logic circuit section.

If the timing verification is determined to be OK at a step S30, the design is completed. At the step S30, if the timing of a certain portion is determined not to satisfy the corresponding timing condition, a modifying process is executed at a step S32 so that a violation portion satisfies the timing condition. The circuit modifying process modifies the circuit containing the wiring. Or, the probing circuit is exchanged or removed. This process may be executed through the input unit 4 by the user or may be automatically executed. For example, when the circuit is modified, the placement position of the probing circuit is changed, and the wiring is made shorter, or the probing circuit is changed to that in which an input capacitance is smaller. Or, as mentioned above, the probing circuit is removed. After that, at a step S34, the timing verifying section 28 activates the automatic placement section 22 and the automatic wiring section 24. In this way, the placement and wiring of the changed portion are executed. After that, the process returns to the step S28, and the above-mentioned steps S28 and S30 are executed.

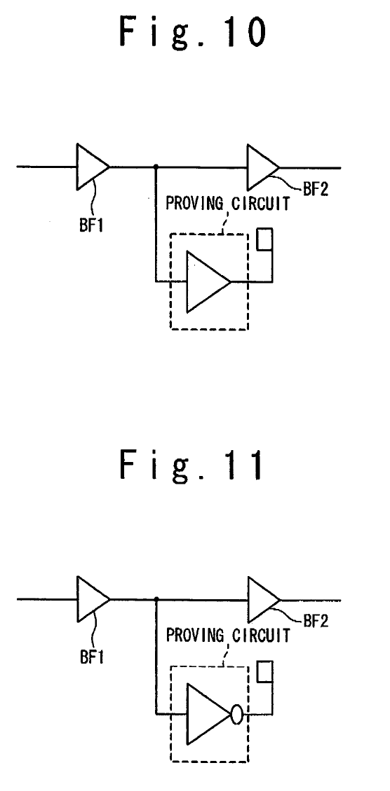

Next, the probing circuit will be described below. FIG. 10 shows an example in which an output signal of a buffer circuit BF1 is specified and the probing circuit is inserted into an output terminal of the buffer circuit BF1. In this example, the probing circuit is a buffer circuit. However, the probing circuit is not limited to the buffer circuit. Any logic circuit may be used. For example, in addition to the buffer circuit, an inverter circuit, an AND circuit, a NAND circuit, an OR circuit, an NOR circuit, a three-state buffer, a flip-flop circuit and a latching circuit may be used as the probing circuit. FIG. 11 shows an example in which the inverter circuit is used as the probing circuit.

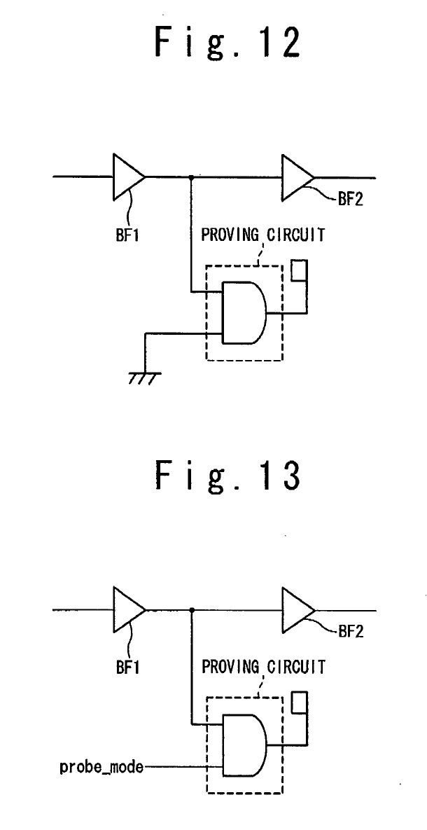

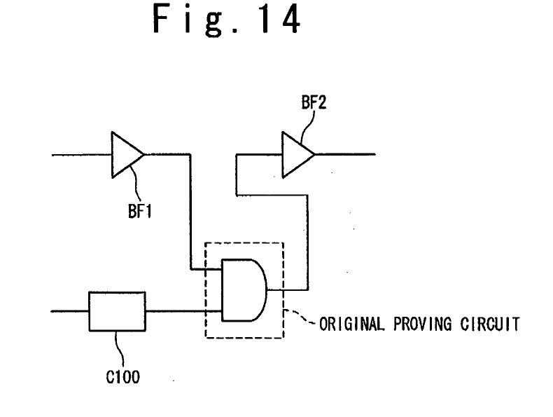

FIG. 12 shows an example in which a two-input AND circuit is used as the probing circuit. One input of the AND circuit is connected to the output of the buffer circuit BF1. The other input of the AND circuit is grounded. In this example, although the other input is grounded, it may be connected to a power source. In any case, the diffusion layer of the transistor, which responds to the change in the output signal of the buffer circuit BF1, is targeted for the LVP method. FIG. 13 shows an example in which the two-input AND circuit is used as the probing circuit, similarly to FIG. 12. One input of the AND circuit is connected to the output of the buffer circuit BF1. A probe mode signal is sent to the other input of the AND circuit. The probe mode signal is the signal which is made active based on an external or internal control signal, when the LVP method is applied. The diffusion layer of the transistor, which responds to the change in the output signal of the buffer circuit BF1 inside the AND circuit, is targeted for the LVP method. In the examples shown in FIGS. 12 and 13, the AND circuit is used as the probing circuit for the LVP method, at the probe mode. After the measurement is ended, this is not required. For this reason, the probing circuit may be considered to be used for another object. For example, this may be used as the spare cell. FIG. 14 shows an example in which it is used as the spare cell.

In FIG. 14, an input line connected to the buffer circuit BF1 is used in its original state. However, the wiring from the buffer circuit BF1 to a buffer circuit BF2 is cut away by laser. On the other hand, a probe mode signal line is connected to an output of a different logic circuit C100. The output of the AND circuit is connected to an input of the buffer circuit BF2. In this way, even if a defect is generated in the buffer circuit BF2 during the manufacturing of the semiconductor device, it is possible to improve the yield by effectively using the AND circuit as the probing circuit. At the same time, a trouble can be modified only by revising the mask in a wiring layer. In this way, the modification can be attained, thereby reducing a modification cost.

According to the present invention, since the circuit section dedicated to the test is installed, the operations of the semiconductor device can be verified under the high reliability, irrespectively of the design rule of the semiconductor device. Also, the operations of the semiconductor device can be verified not only at the logic circuit unit but also any specified circuit block unit. Moreover, the operations of the semiconductor device can be verified without any influence on the other transistors or logic circuits. According to the present invention, it is possible to support the design of the foregoing semiconductor device and manufacture the semiconductor device based thereon.

What is claimed is:

1. A semiconductor device comprising:
a logic circuit section having a plurality of logic circuits and configured to achieve a predetermined logical function; and
a probing circuit connected with said logic circuit section,
wherein said probing circuit is not related to said predetermined logical function and comprises a diffusion layer used in a LVP (Laser Voltage Probing) method.

2. The semiconductor device according to claim 1, wherein said plurality of logic circuits are divided into a plurality of circuit blocks based on a block designation, and
said probing circuit is provided for at least one specified circuit block of said plurality of circuit blocks or at least one specified logic circuit of said plurality of logic circuits.

3. The semiconductor device according to claim 1, wherein said diffusion layer of said probing circuit has a size equal to or larger than a diameter of a laser beam used in said LVP method.

4. The semiconductor device according to claim 1, wherein said probing circuit is one of a buffer circuit, an inverter circuit, an AND circuit, a NAND circuit, an OR circuit, a NOR circuit, a three state buffer circuit, a flip-flop circuit and a latch circuit.

5. The semiconductor device according to claim 1, wherein said semiconductor device comprises a plurality of said probing circuits, and said plurality of probing circuits are different in kind.

6. The semiconductor device according to claim 1, wherein said probing circuit is an AND circuit containing a plurality of transistors,
one of inputs of said AND circuit is connected with said logic circuit section and another one of the inputs of said AND circuit is connected with a mode signal,
said mode signal is outputted when said LVP method is carried out,
at least one of said plurality of transistors is activated in response to said mode signal, and
said diffusion layer of the activated transistor is used for measurement of said LVP method.

7. The semiconductor device according to claim 1, wherein said probing circuit is an AND circuit containing a plurality of transistors,
one of inputs of said AND circuit is connected with said logic circuit section, and another one of the inputs of said AND circuit is connected with a ground voltage or a power supply voltage,
at least one of said plurality of transistor is activated, and
said diffusion layer of the activated transistor is used for measurement of said LVP method.

8. A semiconductor device comprising;
a logic circuit of a plurality of devices; and
a probing circuit connected with an output of at least one device of said plurality of devices,
wherein a diffusion layer of said probing circuit is larger than a diffusion layer of said device.

9. The semiconductor device according to claim 8, wherein an output of said probing circuit is open.

10. The semiconductor device according to claim 8, wherein said probing circuit is activated in a probing mode and is inactivated in a usual operation mode.

11. A design supporting system of a semiconductor device which comprises a logic circuit section having a plurality of logic circuits and configured to achieve a predetermined logical function, and a probing circuit connected with said logic circuit section, wherein said probing circuit is not related to said predetermined logical function and comprises a diffusion layer used in a LVP (Laser Voltage Probing) method, said design supporting system comprising:
a net list configured to store a circuit configuration data showing a configuration of said logic circuit section;
a layout database configured to store first layout data showing a layout of said logic circuit section;
an output unit;
an input unit; and
a processing unit configured to refer to said net list and said layout database, to read out said circuit configuration data from said net list and said first layout data from said layout database, to display the configuration of said logic circuit section on said output unit based on said circuit configuration data, to specify a portion of said logic circuit section as a specification portion in response to a specification instruction from said input unit, to generate a second layout by automatically placement a specification probing circuit in said specification portion of said first layout and automatically connecting said specified probing circuit to said first layout, and to display said second layout on said output unit.

12. The design supporting system according to claim 11, wherein said specification probing circuit is a probing circuit selected from a plurality of probing circuits.

13. The design supporting system according to claim 11, wherein said plurality of logic circuits are divided into a plurality of circuit blocks based on a block specification, and
at least one of said plurality of logic circuits or at least one of said plurality of circuit blocks is specified as said specification portion.

14. The design supporting system according to claim 11, further comprising;
a part database configured to store a part data showing a size and a delay time of a plurality of circuit elements which contain said plurality of logic circuits, and a part data showing a size and a delay time of said probing circuit,
wherein said processing unit refers to said part database and carries out a timing verification based on said second layout.

15. The design supporting system according to claim 14, wherein said processing unit carries out a layout correcting process for modifying said second layout such that a timing condition is met at a specific section of said second layout when said timing condition is not met at said specific section of said second layout in the timing verification.

16. The design supporting system according to claim 15, wherein said layout correcting process is one of a process of replacing a logic circuit in said specific section by another logic circuit having a same logic function as the logic circuit, a process of changing a placement position of said logic circuit in said specific section, and a process of deleting a placed probing circuit in said specific section.

17. The design supporting system according to claim 11, wherein said processing unit specifies said specification portion based on a signal name or a coordinate from said input unit.

18. The design supporting system according to claim 11, wherein said processing unit specifies a non-placement circuit block based on a non-placement block name from said input unit and specifies circuit blocks other than said non-placement circuit block in said logic circuit section as said specification portion.

19. The design supporting system according to claim 18, wherein said processing unit specifies a non-placement signal line based on the non-placement signal name from said input unit and specifies signal lines other than said non-placement signal line in said logic circuit section as said specification portion.

20. The design supporting system according to claim 17, wherein said processing unit inserts said probing circuit into each of inputs and outputs of each of said plurality of logic circuits related to said specification portion.

21. A design supporting method of a semiconductor device which comprises a logic circuit section having a plurality of logic circuits and configured to achieve a predetermined logical function, and a probing circuit connected with said logic circuit section, wherein said probing circuit is not related to said predetermined logical function and comprises a diffusion layer used in a LVP (Laser Voltage Probing) method, said design supporting method comprising:
displaying a configuration of said logic circuit section on an output unit based on a net list;
specifying at least one logic circuit or at least one circuit block which containing said at least one logic circuit in response to an instruction from an input unit as a specification portion; and
automatically placing a specified probing circuit in said specification portion of a first layout and automatically connecting said specified probing circuit to said logic circuit section to generate a second layout.

22. The design supporting method according to claim 21, further comprising:
designating one of a plurality of probing circuits as a specification probing circuit by referring to a part database.

23. The design supporting method according to claim 21, further comprising:
carrying out a timing verification based on said plurality of logic circuits and interconnections in said circuit configuration.

24. The design supporting method according to claim 21, further comprising:
carrying out a layout correcting process for modifying said second layout such that a timing condition is met at a specific section when said timing condition is not met at said specific section of said second layout in the timing verification.

25. The design supporting method according to claim 24, wherein said layout correcting process is one of a process of replacing a logic circuit in said specific section by another logic circuit having a same logic function as the logic circuit, a process of changing a placement position of said logic circuit in said specific section, and a process of deleting a placed probing circuit in said specific section.

26. The design supporting method according to claim 21, wherein said specifying comprises:
specifying as a specification portion, said at least one logic circuit based on a signal name or a coordinate from an input unit and said at least one circuit block based on an placement block name.

27. The design supporting method according to claim 26, wherein said specifying comprises:
specifying a non-placement circuit block based on a non-placement block name from said input unit; and
specifying circuit blocks other than said non-placement circuit block in said logic circuit section as said specification portion.

28. The design supporting method according to claim 26, wherein said specifying comprises:
specifying a non-placement signal line based on the non-placement signal name from said input unit; and
specifying signal lines other than said non-placement signal line in said logic circuit section as said specification portion.

29. The design supporting method according to claim 26, wherein said generating a second layout comprises:
inserting said probing circuit in outputs of said logic circuit and in inputs and outputs of said circuit block in said specification portion.
